(19) United States
(12) Patent Application Publication
(10) Pub. No.: US 2025/0112144 A1
(43) Pub. Date: Apr. 3, 2025

(54) INTEGRATED CIRCUIT PACKAGES INCLUDING A SUBSTRATE HAVING THERMAL ISOMERIC MOIETIES AND NON-THERMAL ISOMERIC MOIETIES

(71) Applicant: Intel Corporation, Santa Clara, CA (US)

(72) Inventor: Mohamed R. Saber, College Station, TX (US)

(73) Assignee: Intel Corporation, Santa Clara, CA (US)

(21) Appl. No.: 18/476,561

(22) Filed: Sep. 28, 2023

(51) Int. Cl. H01L 23/498; H01L 23/15; H05K 1/02; H05K 1/03; H05K 1/11

(52) U.S. Cl. CPC H01L 23/49894; H01L 23/15; H01L 23/49827; H05K 1/0271; H05K 1/0306; H05K 1/116

(57) ABSTRACT

Disclosed herein are microelectronic assemblies and related devices and methods. In some embodiments, a microelectronic assembly may include a glass layer having a surface, the glass layer including conductive through-glass vias (TGVs); and a substrate layer on the surface of the glass layer, the substrate layer including a dielectric material, wherein the dielectric material includes an epoxy having thermal isomeric linkages, non-thermal isomeric linkages, and non-thermal isomeric epoxy monomers, and the thermal isomeric linkages including a cis-dibenzocyclooctane (DBCO) moiety or a tetra derivative DBCO moiety. In some embodiments, the dielectric material includes an epoxy having thermal isomeric epoxy monomers including a cis-DBCO moiety or a tetra derivative DBCO moiety, non-thermal isomeric epoxy monomers, and non-thermal isomeric linkages. In some embodiments, the dielectric material includes a bismaleimide resin or a polyimide resin having non-thermal isomeric monomers and thermal isomeric monomers including a cis-DBCO moiety or a tetra derivative DBCO moiety.

### BACKGROUND

Electronic circuits when fabricated on a wafer of semiconductor material, such as silicon, are commonly called integrated circuits (ICs). The wafer with such ICs is typically cut into numerous individual dies. IC devices (e.g., dies) are typically coupled together in a multi-die IC package to integrate features or functionality and to facilitate connections to other components, such as package substrates. During coupling, the IC package may be exposed to high temperatures and may experience warpage due to uneven thermal expansion of materials, which may cause failures. An IC package may include an embedded multi-die interconnect bridge (EMIB) for coupling two or more dies. An IC package may be integrated onto an electronic system, such as a consumer electronic system. Some ICs have specific functionalities, such as memory or processing. Some other ICs have multiple functionalities, such as a system-on-chip (SOC), in which all or most components of a computer or other electronic system are integrated into a single monolithic die.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic cross-sectional view of an example microelectronic assembly according to some embodiments of the present disclosure.

FIGS. 2A-2C illustrate example thermal isomeric moieties according to some embodiments of the present disclosure.

FIG. 3 is a graphical illustration of CTE values of different dielectric materials over a temperature range according to some embodiments of the present disclosure.

FIG. 4A illustrates a reaction of an example monomer and example curing agents to form a polymer including thermal isomeric moieties and non-thermal isomeric moieties according to some embodiments of the present disclosure.

FIG. 4B illustrates an example portion of a polymer including a thermal isomeric moiety and a non-thermal isomeric moiety according to some embodiments of the present disclosure.

FIG. 5A illustrates a reaction of example monomers and an example curing agent to form a polymer including thermal isomeric moieties and non-thermal isomeric moieties according to some embodiments of the present disclosure.

FIG. 5B illustrates an example portion of a polymer including a thermal isomeric moiety and a non-thermal isomeric moiety according to some embodiments of the present disclosure.

FIG. 6A illustrates a reaction of example monomers self-polymerizing to form a polymer including thermal isomeric moieties and non-thermal isomeric moieties according to some embodiments of the present disclosure.

FIG. 6B illustrates a reaction of other example monomers self-polymerizing to form a polymer including thermal isomeric moieties and non-thermal isomeric moieties according to some embodiments of the present disclosure.

FIGS. 7A and 7B are schematic cross-sectional views of other example microelectronic assemblies according to some embodiments of the present disclosure.

FIGS. 8A-8E are simplified cross-sectional views illustrating various manufacturing steps of a core of an example microelectronic assembly according to some embodiments of the present disclosure.

FIG. 9 is a cross-sectional view of a device package that may include one or more microelectronic assemblies in accordance with any of the embodiments disclosed herein.

FIG. 10 is a cross-sectional side view of a device assembly that may include one or more microelectronic assemblies in accordance with any of the embodiments disclosed herein.

FIG. 11 is a block diagram of an example computing device that may include one or more microelectronic assemblies in accordance with any of the embodiments disclosed herein.

### DETAILED DESCRIPTION

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in a way that limits the broad scope of the present disclosure and its potential applications.

Packaging semiconductor devices presents several challenges. One such challenge is encountered with the demand for miniaturization of semiconductor devices, which has led to an industry push toward die disaggregation since meeting smaller form factors on large, monolithic dies is increasingly difficult. Multi-die IC packaging typically requires increased die stacking and multiple thermal processing steps. Further, in order to meet smaller form factors, some IC packages include a glass core, also referred to herein as a “glass layer,” with vias extending through the glass core for front-to-back connections between two different substrates. A glass core as compared to a conventional epoxy core offers several advantages including higher through-glass via (TGV) density, lower signal losses, and lower total thickness variation (TTV), among others. A substrate may include a dielectric material with conductive pathways therein that are typically formed on a surface of the glass core. The conductive pathways through the dielectric material may provide routing for design flexibility, and the uniform diameters of the TGVs may provide dimensional stability and improved connectivity. The resulting IC packages may suffer from warpage generated as a result of the mismatch in the coefficient of thermal expansion (CTE) between a substrate and a glass layer.

Fabrication of an IC package is a multi-step process, which may include fabricating sub-assemblies that are incorporated into an IC package. An example sub-assembly may include a heterogenous package having one or more top dies coupled to a substrate on a glass layer with a mold material surrounding the top dies. In some embodiments, the one or more top dies may be coupled directly to a package substrate (e.g., a substrate on a glass layer), overmolded, and then coupled to a circuit board. A first plurality of solder bump structures (e.g., solder bumps, balls, pads, pillar bumps (e.g., copper pillar bumps), etc.) of a generally uniform size can be positioned between the top die and the substrate, and then heated to similar temperatures. The top die may then be lowered onto the substrate, in order to mechanically and electrically couple the top die to the substrate. Heat can be applied via a solder reflow process to re-melt the solder bumps and attach the top die to the substrate forming interconnects, which may further be underfilled with a non-conductive adhesive to strengthen the mechanical connection between the top die and the substrate. Manufacturing of an IC package can involve multiple thermal cycling (or processing) steps. For example, multiple layers of a substrate may be formed on a glass layer, which requires depositing a dielectric material and curing using a thermal cycle for each layer of the substrate. In another example, a die may be heated to add solder balls (e.g., flip-chip or controlled collapse chip connection (C4) solder balls). The die may again be heated one or more times for placement and solder reflow. Another thermal cycle may be added if epoxy, for example, is used in the assembly process as an underfill material. An underfilling process, such as capillary flow underfilling, relies upon capillary pressure of the underfill material, to flow between the top die and the base die. More thermal cycles may be used to incorporate the IC package into an electronic assembly.

The multiple thermal cycles can lead to warpage of components of an IC package. Warpage refers to a bending or twist or general lack of flatness in a plane. A lack of flatness may occur where the entire package warps so that it is curved or bent or otherwise non-flat. Such warpage is typically caused by a difference in CTE between one part or component and another. Various ones of the embodiments disclosed herein may help achieve improved performance of IC packages, by incorporating materials having similar CTEs over the range of thermal exposure, relative to conventional approaches.

Accordingly, disclosed herein are microelectronic assemblies and related devices and methods. In some embodiments, a microelectronic assembly may include a glass layer having a surface, the glass layer including conductive through-glass vias (TGVs); and a substrate layer on the surface of the glass layer, the substrate layer including a dielectric material, wherein the dielectric material includes an epoxy having thermal isomeric linkages, non-thermal isomeric linkages, and non-thermal isomeric epoxy monomers, and wherein the thermal isomeric linkages include a cis-dibenzocyclooctane (DBCO) moiety or a tetra derivative DBCO moiety. In some embodiments, the dielectric material includes an epoxy having thermal isomeric epoxy monomers including a cis-DBCO moiety or a tetra derivative DBCO moiety, non-thermal isomeric epoxy monomers, and non-thermal isomeric linkages. In some embodiments, the dielectric material includes a bismaleimide resin or a polyimide resin having non-thermal isomeric monomers and thermal isomeric monomers including a cis-DBCO moiety or a tetra derivative DBCO moiety. A thermal isomeric moiety may include a cis-dibenzocyclooctane (DBCO) moiety, such as 2, 9-DBCO or 1, 10-DBCO, or a tetra derivative DBCO moiety, such as 1, 4, 7, 10-DBCO.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are stated in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may include substantially monocrystalline semiconductors, such as silicon or germanium, as a base material on which integrated circuits are fabricated with traditional semiconductor processing methods. The semiconductor base material may include, for example, N-type or P-type materials. Dies may include, for example, a crystalline base material formed using a bulk silicon (or other bulk semiconductor material) or a semiconductor-on-insulator (SOI, e.g., a silicon-on-insulator) structure. In some other embodiments, the base material of one or more of the IC dies may include alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may include compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may include an intrinsic IV or III-V semiconductor material or alloy, not intentionally doped with any electrically active impurity; in alternate embodiments, nominal impurity dopant levels may be present. In still other embodiments, dies may include a non-crystalline material, such as polymers; for example, the base material may include silica-filled epoxy. In other embodiments, the base material may include high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of input/output (I/O) functions, arithmetic operations, pipelining of data, etc.).

In another example, the terms “package” and “IC package” are synonymous, as are the terms “die” and “IC die.” Note that the terms “chip,” “chiplet,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may include a semiconductor material, for example, N-type or P-type materials. The PIC may include, for example, a crystalline base material formed using a bulk silicon (or other bulk semiconductor material) or a SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-N or group IV materials. In some embodiments, the PIC may include a non-crystalline material, such as polymers. In some embodiments, the PIC may be formed on a printed circuit board (PCB). In some embodiments, the PIC may be inhomogeneous, including a carrier material (such as glass or silicon carbide) as a base material with a thin semiconductor layer over which is an active side including transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., metal oxide semiconductor (MOS) FETs (MOSFETs). In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are included in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a PIC, “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO2), borosilicate (e.g., 70-80 wt % SiO2, 7-13 wt % of B203, 4-8 wt % Na₂O or K2O, and 2-8 wt % of Al2O3) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material includes interlayer low-k dielectric that is provided within the IC die. Within package substrates, and printed circuit boards (PCBs) such insulating material includes organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substrate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI). Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects. In some embodiments, the pitch of the DTD interconnects may be different from the pitch of the DTPS interconnects, although, in other embodiments, these pitches may be substantially the same.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may include the same or different insulating materials. In some embodiments, the levels of underfill may include thermoset epoxies with silicon oxide particles; in some embodiments, the levels of underfill may include any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example,” an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

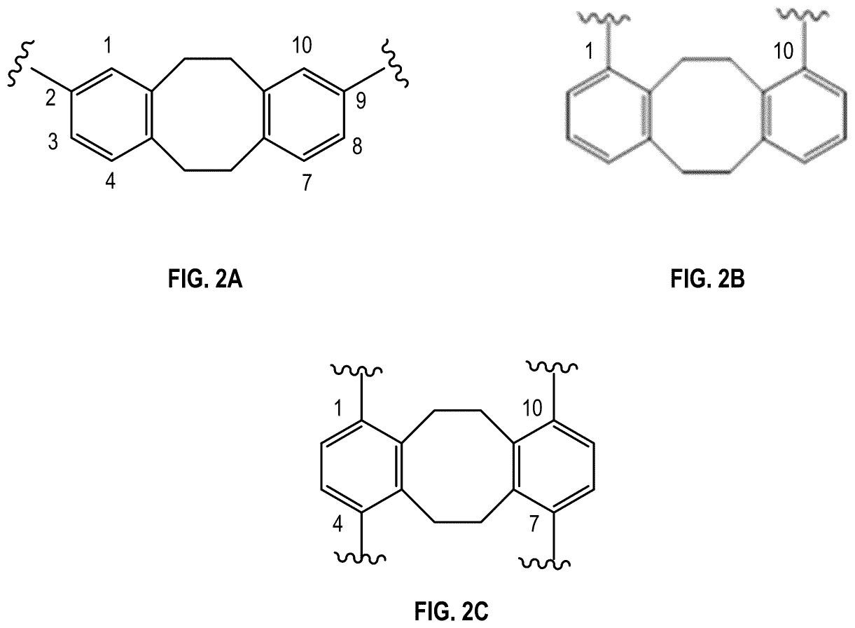

For convenience, if a collection of drawings designated with different letters are present (e.g., FIGS. 2A-2C), such a collection may be referred to herein without the letters (e.g., as “FIG. 2”). Similarly, if a collection of reference numerals designated with different numbers and/or letters are present (e.g., 148-1, 148-2), such a collection may be referred to herein without the numbers (e.g., as “148”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

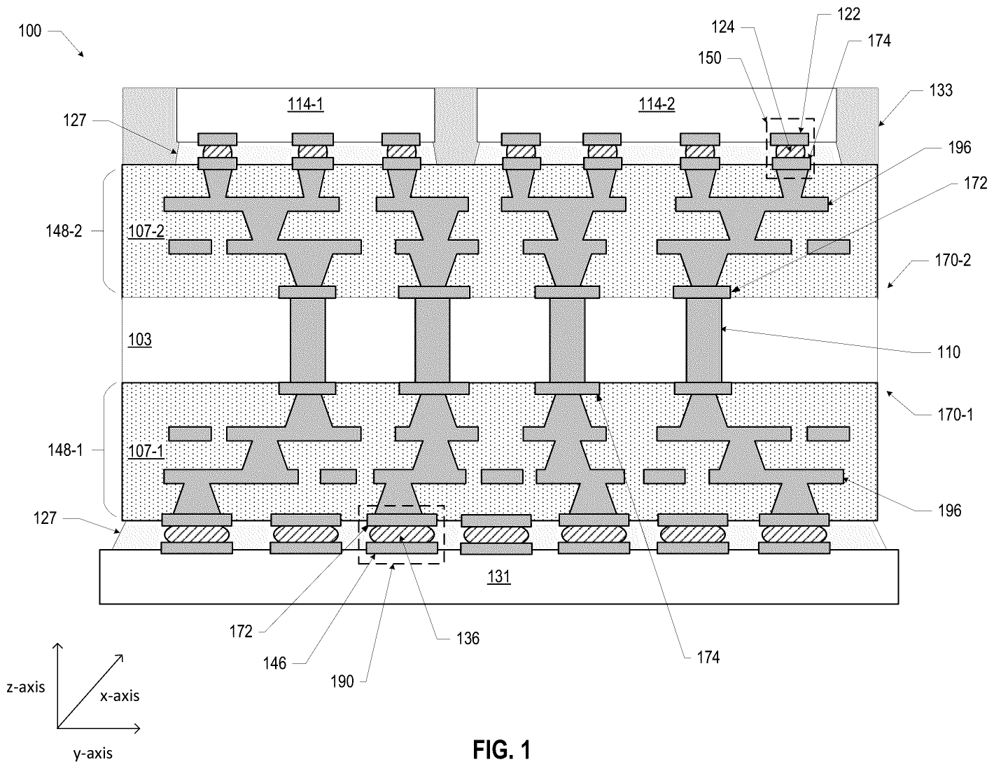

FIG. 1 is a schematic cross-sectional view of an example microelectronic assembly 100 according to some embodiments of the present disclosure. Microelectronic assembly 100 may include a core 103 having TGVs 110, and a first substrate 148-1 at a first surface 170-1 of the core 103 and a second substrate 148-2 at an opposing second surface 170-2 of the core 103. TGVs 110 may extend through the core 103 from the first surface 170-1 to the second surface 170-2. A material of the core 103 may include glass, such as bulk transparent glass, which is different than a fiberglass that is typically used in reinforced epoxy cores for package substrates or motherboards. Moreover, in various embodiments, the glass of core 103 is not explicitly combined with any organic material but rather includes any type of bulk amorphous or polycrystalline transparent, opaque, or semi-transparent glass, including fused silica, borosilicate glass, soda-lime glass, ceramic glass, etc. In such embodiments, the core 103 may be referred to herein as “a glass layer.” In some embodiments, a thickness (e.g., z-height) of a core 103 may be between 25 microns and 2 millimeters (i.e., between 100 microns and 1 millimeter). The first and second substrates 148-1, 148-2 may include conductive pathways 196 (e.g., including conductive traces and/or conductive vias, as shown) through a dielectric material 107-1, 107-2, respectively.

A dielectric material 107 of the substrate 148 may include a polymer having a thermal isomeric moiety and a non-thermal isomeric moiety. A polymer may include, for example, an epoxy (e.g., epoxy build-up films, or the like), a bismaleimide resin, or a polyimide resin. A thermal isomeric moiety may include dibenzocyclooctane (DBCO), which undergoes a reversible twist-boat to chair isomerization upon heating. In some embodiments, a thermal isomeric moiety may include a cis-DBCO derivative, for example, 1, 9-DBCO, as shown in FIG. 2A, or, in another example, 1, 10-DBCO, as shown in FIG. 2B. In some embodiments, a thermal isomeric moiety may include a tetra derivative DBCO, for example, 1, 4, 7, 10-DBCO, as shown in FIG. 2C. The thermal isomeric moieties of FIGS. 2A-2C are collectively referred to herein as TI-DBCO. The reversible isomerization of TI-DBCO may effectively reduce a CTE of a material upon heating. In some embodiments, a dielectric material 107 may further include inorganic fillers, such as silica or alumina. TI-DBCO thermal moieties may be detected using any suitable technique or techniques, including, for example, proton nuclear magnetic resonance (proton NMR or hydrogen-1 NMR), carbon-13 NMR spectroscopy, gas chromatography-mass spectrometry (GC-MS), and X-ray crystallography. In some embodiments, detection may require depolymerization processes to separate into TI-DBCO based monomeric components. Further techniques for detecting TI-DBCO moieties may include variable temperature NMR spectroscopy, thermomechanical analysis, and differential scanning calorimetry (DSC) to detect electronic and calorimetric changes associated with the thermal isomerization of DBCO between the twist-boat and chair isomers including the low CTE values.

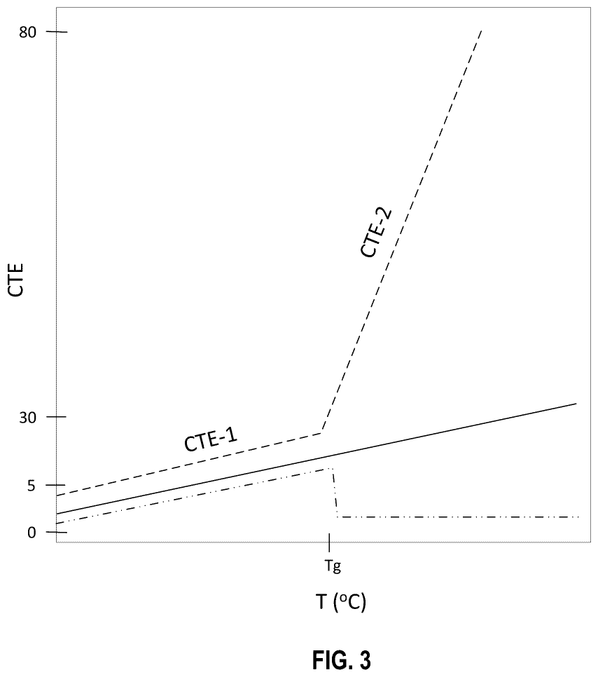

FIG. 3 is a graphical illustration of CTE values of different dielectric materials over a temperature range according to some embodiments of the present disclosure. A dielectric material generally has two CTE values: CTE-1 (e.g., CTE value below a glass transition temperature for the material) and CTE-2 (e.g., CTE value above a glass transition temperature for the material). One challenge with incorporating substrates on a glass layer is that a material of the glass layer and a material of the substrate typically have different CTEs. A conventional dielectric material of the substrate including inorganic fillers has a large, positive CTE-1 value of approximately 20 parts per million per degree Celsius (ppm/° C.) and CTE-2 value of approximately 100 ppm/° C., conductive pathways through the dielectric material of the substrate have a CTE value of approximately 17 ppm/° C., and a glass layer has a low CTE value of approximately 5 ppm/° C. The different CTEs create stresses in the IC package arising from uneven thermal expansion between the substrate, the conductive pathways, and the glass layer. These residual stresses are likely to cause warpage, fractures and/or cracks in the glass layer, delamination of the conductive pathways and/or dielectric material of the substrate from the glass layer. These stresses also cause the glass layer to become more susceptible to mechanical stresses and cracks during substrate handling and singulation as well as malfunctions, failures, and other reliability issues during use. Package warpage is a significant challenge as it impacts the ability to handle the package during assembly steps. In addition, package warpage produces yield losses, which increases costs especially in heterogenous packages because multiple dies are discarded even if only a single die fails. As such, package warpage is therefore a major problem for package designs.

One way to mitigate or minimize the stress between the substrate and the glass layer is to include materials having a same or similar CTE over the range of thermal exposure (e.g., the CTE-1 and CTE-2 of the dielectric material of the substrate have similar values to the CTE of the glass layer over the range of thermal exposure). A common solution to equalizing CTEs is to add inorganic fillers, such as silica or alumina, which have low CTEs of approximately 6 and 8 ppm/° C., respectively, to a dielectric material to reduce the overall CTE of the dielectric material. The effect of inorganic fillers to reduce the CTE-1 of a dielectric material is limited by a resulting high CTE-2 value of the dielectric material (e.g., as shown below with reference to FIG. 3), by the amount of inorganic filler that may be added without having a detrimental impact on other desired properties of the dielectric material, such as dielectric constant and modulus, and some dielectric materials, such as varnish type dielectrics, are not compatible with inorganic fillers due to the differences in densities between the materials.

As shown in FIG. 3, dielectric materials generally have two CTE values: CTE-1 (e.g., below a glass transition temperature for the material) and CTE-2 (e.g., above a glass transition temperature for the material). A conventional dielectric material that includes inorganic fillers to reduce the CTE value, as shown by the dotted line, typically has a CTE-1 value equal to approximately 25 parts per million per degrees Celsius (ppm/° C.) and a CTE-2 equal to approximately 80 ppm/° C. A dielectric material that includes thermal isomeric moieties, such as DBCO, (and does not include non-thermal isomeric moieties or inorganic fillers), as shown by the dashed and dotted line, may have a CTE-1 value equal to approximately 20 ppm/° C. and a CTE-2 value equal to approximately 0 ppm/° C. or may even have a negative CTE-2 value. As shown by the solid line, a dielectric material that includes thermal isomer moieties and non-thermal isomeric moieties (e.g., the dielectric material 107 in FIG. 1) may be tuned to optimize CTE-1 and CTE-2 values, such that a CTE-1 value is between 3 ppm/° C. and 20 ppm/° C. and a CTE-2 value is between 5 ppm/° C. and 55 ppm/° C. In some embodiments, inorganic fillers may be included in a dielectric material that has thermal isomeric and non-thermal isomeric moieties to reduce the CTE-1 and CTE-2.

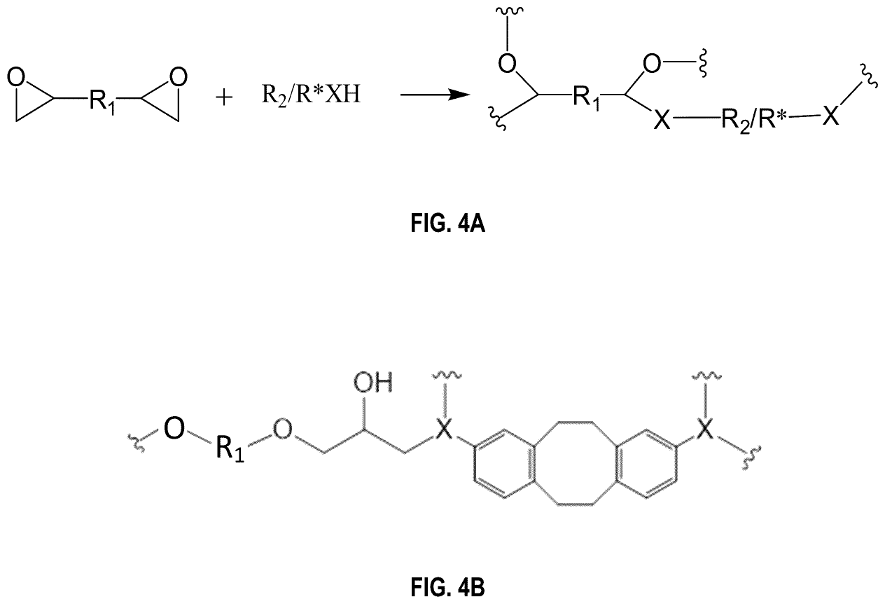

A thermal isomeric moiety (e.g., TI-DBCO) may be incorporated into a polymer as a linkage between monomers or may be incorporated as part of a monomer. FIG. 4A illustrates a reaction of an example monomer and example curing agents to form a polymer including thermal isomeric moieties and non-thermal isomeric moieties according to some embodiments of the present disclosure. As shown in FIG. 4A, a reaction may include R₁-epoxy monomers, where R₁ is an aromatic or aliphatic moiety (e.g., non-thermal isomeric, such as bisphenol F epoxy or bisphenol A epoxy), a non-thermal isomeric curing agent R₂XH, where R₂ is an aromatic or aliphatic moiety, X is nitrogen (N), oxygen (O), or sulfur(S), and a thermal isomeric curing agent R*XH, where R* includes a TI-DBCO moiety. In some embodiments, a non-thermal isomeric curing agent R₂XH may include an amine, a polyamide, an amidoamine, an anhydride, an ester, a Lewis acid, an organic acid (e.g., carboxylic acid), a phenol, or a thiol. FIG. 4B illustrates an example portion of a polymer including a thermal isomeric moiety and a non-thermal isomeric moiety according to some embodiments of the present disclosure. FIG. 4B illustrates a portion of a polymer formed from the reaction of FIG. 4A, where R* a TI-DBCO moiety and is incorporated as a linkage between the non-thermal isomeric R₁ epoxy monomers. The polymer of FIG. 4B will further include non-thermal isomeric linkages R₂ (not shown in FIG. 4B) between the R₁ epoxy monomers. The relative amounts (e.g., a ratio) of thermal isomeric linkages R* and non-thermal isomeric linkages R₂ may be determined based on desired CTE-1 and CTE-2 values for the polymer (e.g., the dielectric material 107). CTE values of a material may be determined using thermal mechanical analysis (TMA).

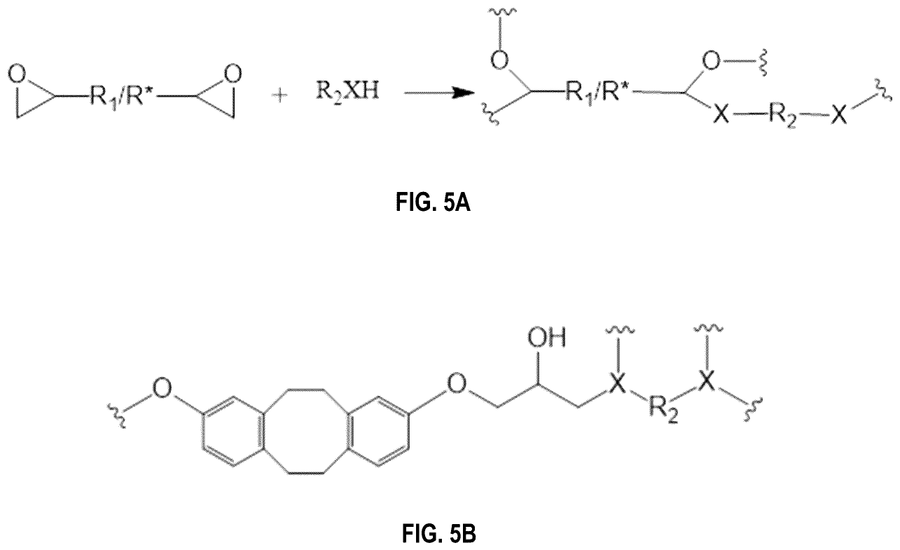

FIG. 5A illustrates a reaction of example monomers and an example curing agent to form a polymer including thermal isomeric moieties and non-thermal isomeric moieties according to some embodiments of the present disclosure. As shown in FIG. 5A, a reaction may include non-thermal isomeric R₁-epoxy monomers, where R₁ is an aromatic or aliphatic moiety (e.g., bisphenol F epoxy or bisphenol A epoxy), thermal isomeric R*-epoxy monomers, where R* includes a TI-DBCO moiety, and a non-thermal isomeric curing agent R₂XH, where R₂ is an aromatic or aliphatic moiety, and X is nitrogen (N), oxygen (O), or sulfur(S). In some embodiments, a non-thermal isomeric curing agent R₂XH may include an amine, a polyamide, an amidoamine, an anhydride, an ester, a Lewis acid, an organic acid (e.g., carboxylic acid), a phenol, or a thiol. FIG. 5B illustrates an example portion of a polymer including a thermal isomeric moiety and a non-thermal isomeric moiety according to some embodiments of the present disclosure. FIG. 5B illustrates a portion of a polymer formed from the reaction of FIG. 5A, where R* is a TI-DBCO moiety incorporated as a part of the monomers connected by the non-thermal isomeric R₂ linkages. The polymer of FIG. 5B will further include non-thermal isomeric R₁-epoxy monomers (not shown in FIG. 5B). The relative amounts (e.g., a ratio) of thermal isomeric R*-epoxy monomers and non-thermal isomeric R₁-epoxy monomers may be determined based on desired CTE-1 and CTE-2 values for the polymer (e.g., the dielectric material 107). CTE values of a material may be determined using TMA.

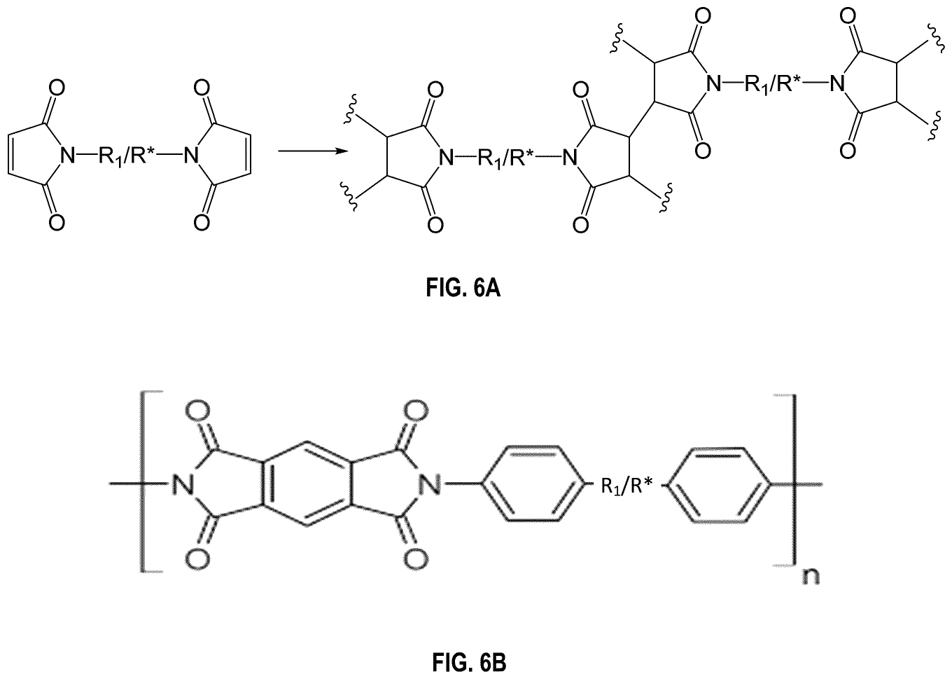

FIGS. 6A and 6B illustrate example non-epoxy monomers that self-polymerize to form a polymer including thermal isomeric moieties and non-thermal isomeric moieties according to some embodiments of the present disclosure. As shown in FIG. 6A, a reaction may include non-thermal isomeric R₁-bismaleimide monomers, where R₁ is an aromatic or aliphatic moiety, and thermal isomeric R*-bismaleimide monomers, where R* includes a TI-DBCO moiety, to form a bismaleimide (BMI) resin including thermal isomeric moieties and non-thermal isomeric moieties. As shown in FIG. 6B, a polyimide (PI) resin may include non-thermal isomeric R₁ moieties, where R₁ is an aromatic or aliphatic moiety, and thermal isomeric R*moieties, where R* includes a TI-DBCO moiety. The relative amounts (e.g., a ratio) of thermal isomeric R* monomers and non-thermal isomeric R₁ monomers may be determined based on desired CTE-1 and CTE-2 values for the BMI resin and the PI resin (e.g., the dielectric material 107). CTE values of a material may be determined using TMA.

Returning to FIG. 1, the conductive pathways 196 in the first substrate 148-1 may be electrically coupled to TGVs 110 at the first surface 170-1 of the core 103 and the conductive pathways in the second substrate 148-2 may be electrically coupled to the TGVs 110 at the second surface 170-2 of the core 103. The TGVs 110 in the core 103 may electrically couple the first and second substrates 148-1, 148-2. The substrates 148 may include a set of first conductive contacts 172 at the bottom surface of the substrate 148 and a set of second conductive contacts 174 at the top surface of the substrate 148, where the conductive pathways 196 electrically couple individual ones of the first and second conductive contacts 172, 174. The first and second substrates 148-1, 148-2 may be manufactured using any suitable technique, such as conventional substrate package or PCB manufacturing processing (e.g., a semi-additive plating process, etc.). TGVs 110 may have any suitable size and shape. TGVs 110 are shown in FIG. 1 as having straight, parallel edges; however, in various embodiments, TGVs 110 may be tapered and/or have other irregularities depending on the processing conditions for generating TGVs 110. A TGV 110 may have a same diameter 197 through the core 103 (e.g., diameter is substantially equal over a thickness (e.g., z-height)), or a TGV 110 may have a tapered or angled contour (e.g., an hourglass shape), where the TGV 110 has a narrower diameter in a middle of the core 103 and thicker diameters at the first and second surfaces 170-1, 170-2, respectively. In some embodiments, a diameter of the individual TGVs 110 may be between 10 microns and 200 microns (e.g., between 35 microns and 75 microns). TGVs 110 may be formed using any suitable process, including, for example, laser drilling via openings through the core 103 and depositing a conductive material in the openings. TGVs 110 may be formed of any suitable conductive material, such as copper, silver, nickel, gold, aluminum, or other metals or alloys. In some embodiments, a pitch of the TGVs 110 may be between 50 microns and 200 microns (e.g., between 75 microns and 150 microns).

The microelectronic assembly 100 may further include die 114-1 and die 114-2 electrically coupled to a top surface of the second substrate 148-2 by interconnects 150. In particular, conductive contacts 122 on a bottom surface of die 114-1, 114-2 may be electrically and mechanically coupled to conductive contacts 174 at a top surface of the second substrate 148-2 by interconnects 150. Interconnects 150 may enable electrical coupling between die 114-1 and die 114-2 through conductive pathways 196 in substrate 148-2. Interconnects 150 disclosed herein may take any suitable form. In some embodiments, a set of interconnects 150 may include solder 124 (e.g., solder bumps or balls that are subject to a thermal reflow to form the interconnects 150). In some embodiments, interconnects 150 may include solder 132 (e.g., solder bumps or balls that are subject to a thermal reflow to form the interconnects 150). Interconnects 150 that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of interconnects 150 may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression. In some embodiments, interconnects 150 disclosed herein may have a pitch between about 18 microns and 75 microns.

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imagable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). The conductive pathways in the dies 114 may be bordered by liner materials, such as adhesion liners and/or barrier liners, as suitable. In some embodiments, the die 114 is a wafer. In some embodiments, the die 114 is a monolithic silicon, a fan-out or fan-in package die, or a die stack (e.g., wafer stacked, die stacked, or multi-layer die stacked). In various embodiments, die 114 may include, or be a part of, one or more of a central processing unit (CPU), a memory device (e.g., a high-bandwidth memory device), a logic circuit, input/output circuitry, a transceiver such as a field programmable gate array transceiver, a gate array logic such as a field programmable gate array logic, of a power delivery circuitry, a III-V or a III-N device such as a III-N or III-N amplifier (e.g., GaN amplifier), Peripheral Component Interconnect Express (PCIe) circuitry, Double Data Rate (DDR) transfer circuitry, or other electronic components known in the art. In some embodiments, die 114-1 and die 114-2 may include different functionalities. As used herein, the term “functionality” with reference to a die refers to one or more functions (e.g., capability, task, operation, action, instruction execution, etc.) that the die in question can perform. For example, die 114-1 may be a CPU and die 114-2 may be a Graphics Processing Unit (GPU) or memory. In other embodiments, die 114-1 and die 114-2 may include the same or similar functionalities. For example, die 114-1 and die 114-2 may each include memory.

The microelectronic assembly 100 of FIG. 1 may also include an insulating material 133 that encapsulates the die 114 (e.g., on and around die 114 and interconnects 150). The insulating material 133 may extend from a top surface of the second substrate 148-2 to a top surface of the die 114. In some embodiments, the insulating material 133 may be a mold material, such as an organic polymer with inorganic silicon oxide or aluminum oxide particles, a resin material, or an epoxy material. In some embodiments (not shown) other components, such as heat sinks may be coupled to microelectronic assembly 100 based on particular needs.

The microelectronic assembly 100 of FIG. 1 may also include an underfill material 127. In some embodiments, the underfill material 127 may extend between die 114-1, 114-2 and the second substrate 148-2 around the associated interconnects 150. The underfill material 127 may include any suitable underfill material, including as described above with reference to a material 105. In some embodiments, the underfill material 127 may extend between the second substrate 148-2 and the die 114-1, 114-2 around the associated interconnects 150. In some embodiments, an underfill material 127 may be omitted. Although FIG. 1 shows two separate underfill material 127 portions under die 114-1 and die 114-2, the underfill material 127 may be a single underfill material 127 under die 114-1 and die 114-2. The underfill material 127 may be selected to have a CTE that may mitigate or minimize the stress between die 114 and the second substrate 148-2 arising from uneven thermal expansion in the microelectronic assembly 100. In some embodiments, the CTE of the underfill material 127 may have a value that is intermediate to the CTE of the second substrate 148-2 (e.g., the CTE of the dielectric material 107 of the substrate 148) and a CTE of the insulating material of die 114.

The microelectronic assembly 100 of FIG. 1 may also include a circuit board 131. In particular, conductive contacts 172 on a bottom surface of the first substrate 148-1 may be electrically coupled to conductive contacts 146 on a top surface of circuit board 131 by interconnects 190. Interconnects 190 disclosed herein may take any suitable form, including solder balls for a ball grid array arrangement, pins in a pin grid array arrangement or lands in a land grid array arrangement, or any of the forms described above with reference to interconnects 150. As shown in FIG. 1, in some embodiments, a set of interconnects 190 may include solder 136 (e.g., solder bumps or balls that are subject to a thermal reflow to form the interconnects 190). In some embodiments, the interconnects 190 disclosed herein may have a pitch between about 50 microns and 300 microns. In some embodiments, an underfill material 127 may extend between the first substrate 148-1 and the circuit board 131 around the associated interconnects 190. The circuit board 131 may be a motherboard, for example, and may have other components attached to it. The circuit board may include conductive pathways and other conductive contacts for routing power, ground, and signals through the circuit board, as known in the art. In some embodiments, the interconnects 190 may not couple to a circuit board 131, but may instead couple to another IC package, an interposer, or any other suitable component.

As used herein, the core 103 with the second substrate 148-2 and/or the first substrate 148-1 may be referred to as a package substrate. TGVs 110 in core 103 may enable power, ground and signal connectivity to components located on either side of the core 103, for example, between dies 114-1, 114-2 and a circuit board 131.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

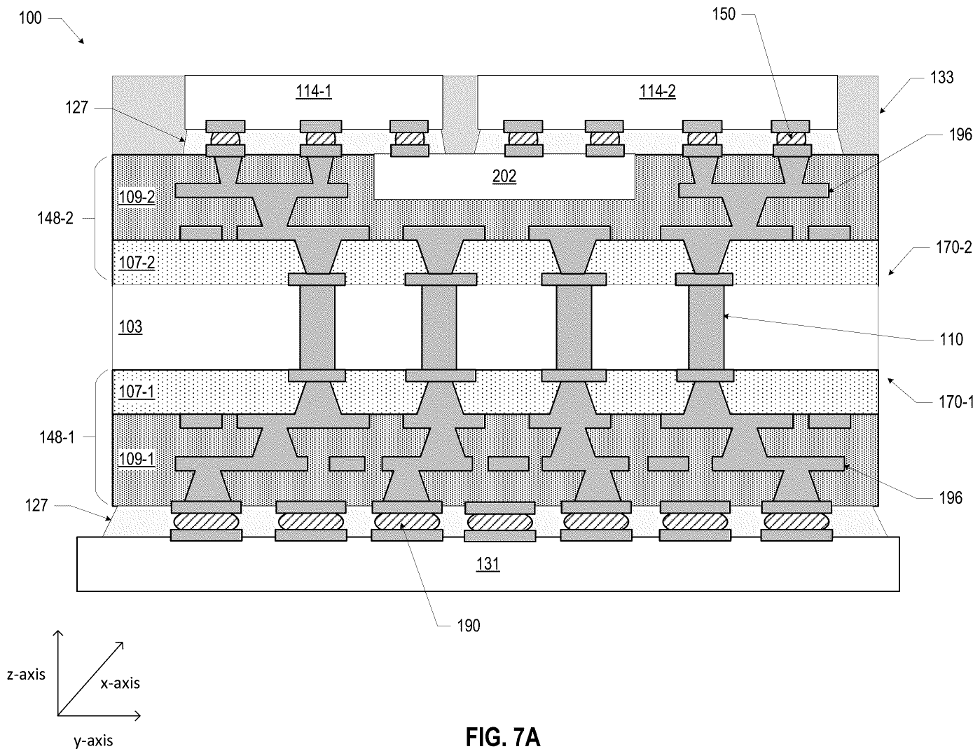

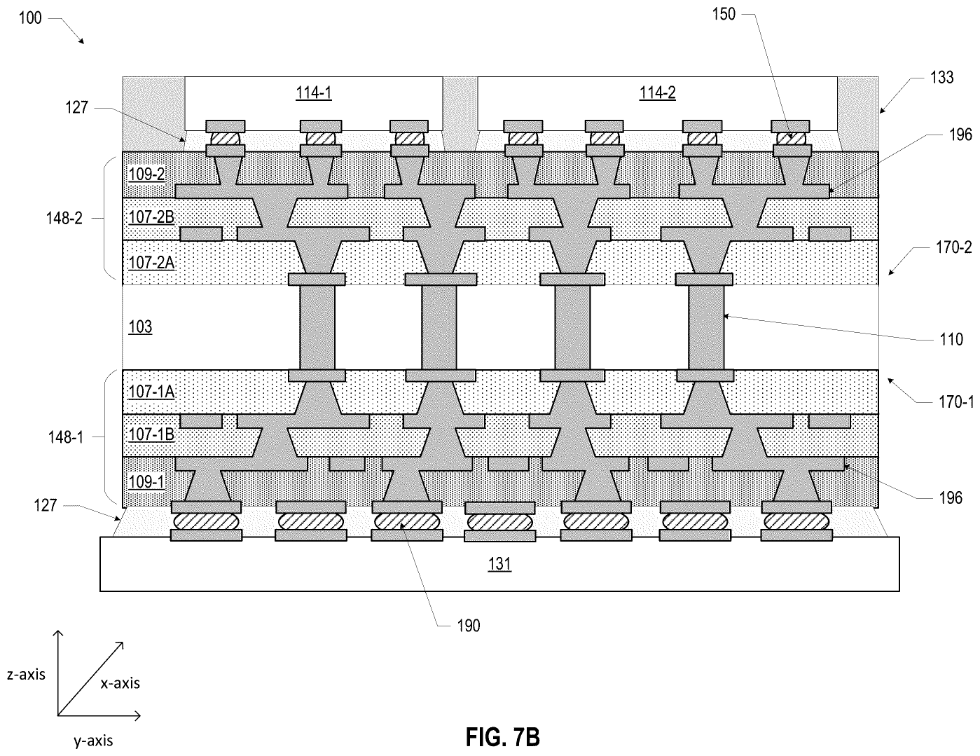

FIG. 7A is a schematic cross-sectional view of another example microelectronic assembly 100 according to some embodiments of the present disclosure. The configuration of the embodiment shown in the figure is like that of FIG. 1, except for differences as described further. The configuration of microelectronic assembly 100 as described herein further includes a layer of conventional dielectric material 109-1, 109-2 (e.g., dielectric material that does not include thermal isomeric moieties) on the buffer layers of dielectric material 107-1, 107-2, respectively. The layer of conventional dielectric material 109 may include bismaleimide triazine (BT) resin, polyimide materials, epoxy materials (e.g., glass reinforced epoxy matrix materials, epoxy build-up films, or the like), mold materials, oxide-based materials (e.g., silicon dioxide or spin on oxide), or low-k and ultra low-k dielectric (e.g., carbon-doped dielectrics, fluorine-doped dielectrics, porous dielectrics, and organic polymeric dielectrics), and may have a CTE-1 value of approximately 10-30 ppm/° C. and CTE-2 value of approximately 30-110 ppm/° C. The configuration of microelectronic assembly 100 in FIG. 7A further includes a bridge die 202. A bridge die 202 may be at least partially within a dielectric material 109-2 of the second substrate 148-2 (e.g., at least partially nested in a cavity). The bridge die 202 may be electrically coupled to dies 114 (e.g., die 114-1 and die 114-2) by interconnects 150. In particular, conductive contacts 122 on the bottom surface of dies 114 may be electrically and mechanically coupled to the conductive contacts 125 on the top surface of the bridge die 202 by interconnects 150. A bridge die 202 may comprise appropriate circuitry on/in a semiconductor substrate to connect at silicon-interconnect speeds with a small footprint. In some embodiments, bridge die 202 may comprise active components, such as transistors and diodes in addition to bridge circuitry including metallization traces, vias and passive components for enabling electrical coupling between two ICs; in other embodiments, bridge die 202 may include bridge circuitry including metallization traces, vias and passive components for enabling electrical coupling between die 114-1 and die 114-2, and may not include active components. In some embodiments, a bridge die 202 may include a double-sided that further includes conductive contacts on a bottom surface (not shown). In particular, conductive contacts on a bottom surface of the bridge die 202 may be electrically coupled to conductive pathways 196 of the second substrate 148-2. In some embodiments, bridge die 202 may include through substrate vias (TSVs) (not shown). A “bridge die” also may be referred to herein as an “interconnect die.”

FIG. 7B is a schematic cross-sectional view of another example microelectronic assembly 100 according to some embodiments of the present disclosure. The configuration of the embodiment shown in the figure is like that of FIG. 7A, except without a bridge die 202 and for differences as described further. The configuration of microelectronic assembly 100 as described herein further includes first layers of dielectric material 107-1A, 107-2A on respective surfaces 170-1, 170-2 of the core 103, second layers of dielectric material 107-1B, 107-2B on respective first layers of dielectric material 107-1A, 107-2A, and third layers of conventional dielectric material 109-1, 109-2 (e.g., dielectric material that does not include thermal isomeric moieties and may include inorganic fillers) on the respective second layers of dielectric material 107-1B, 107-2B. The first, second, and third layers of dielectric material 107, 109 may have different CTE-2 values that increase moving away from the core 103. The first layers of dielectric material 107-1A, 107-2A may have a first CTE-2 value between 5 ppm/° C. and 55 ppm/° C. (e.g., the first CTE-2 value based on a first ratio of thermal isomeric moieties and non-thermal isomeric moieties, and may further include inorganic fillers). The second layers of dielectric material 107-1B, 107-2B may have a second CTE-2 value between 25 ppm/° C. and 65 ppm/° C. (e.g., the second CTE-2 value based on a second ratio of thermal isomeric moieties and non-thermal isomeric moieties, and may further include inorganic fillers). The third layers of conventional dielectric material 109-1, 109-2 may have a third CTE-2 value between 30 ppm/° C. and 110 ppm/° C.

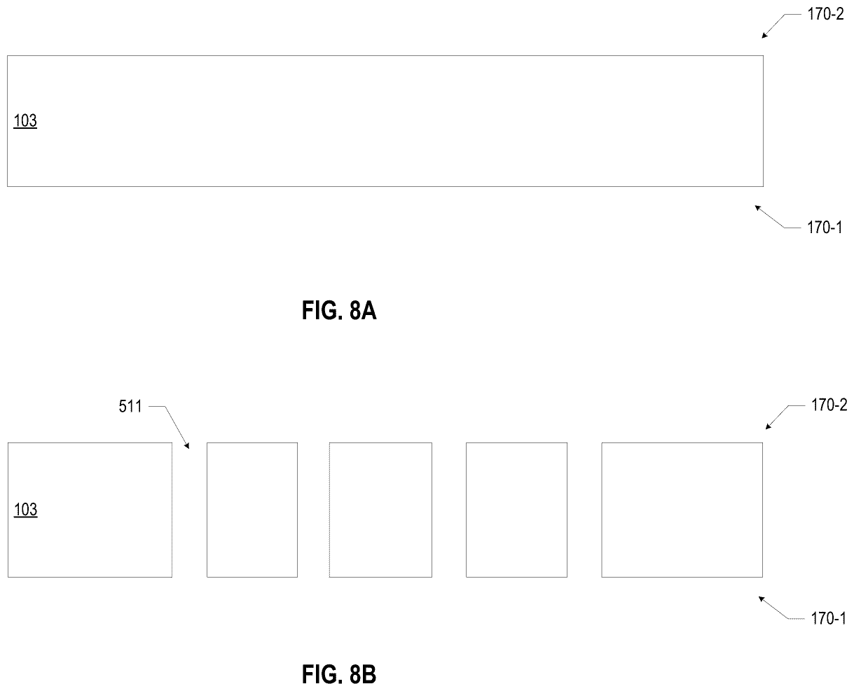

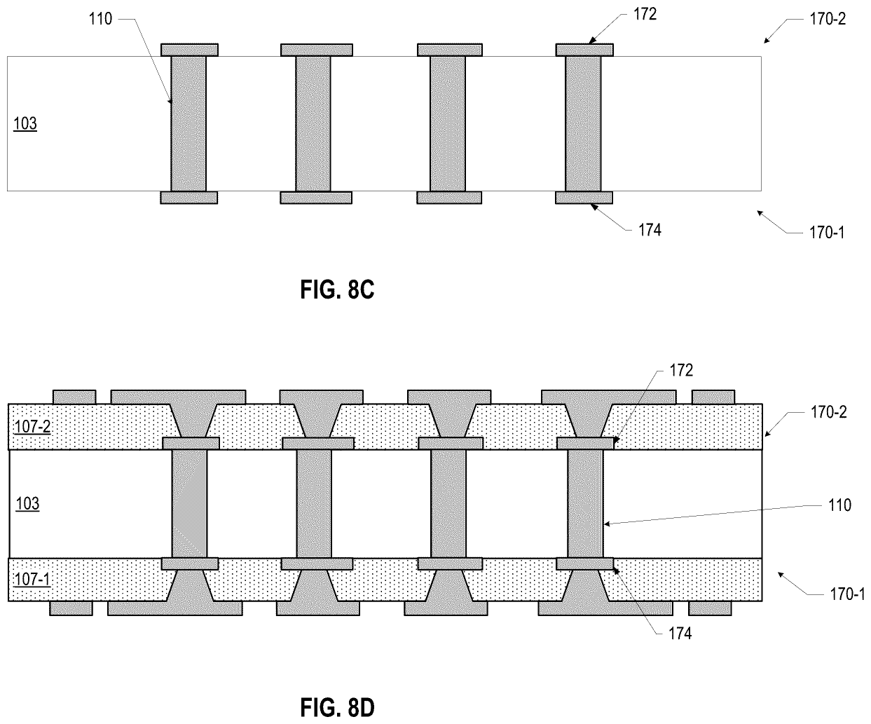

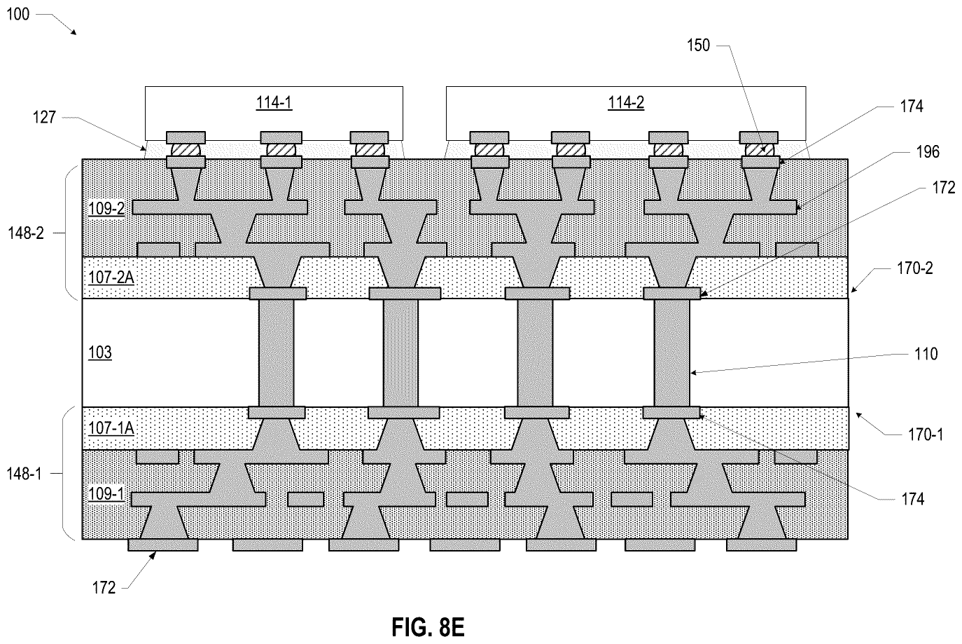

Any suitable techniques may be used to manufacture the microelectronic assemblies 100 disclosed herein. For example, FIGS. 8A-8E are side, cross-sectional views of various stages in an example process for manufacturing the microelectronic assembly 100 of FIG. 7A, in accordance with various embodiments. Although the operations discussed below with reference to FIGS. 8A-8E (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 8A-8E may be modified in accordance with the present disclosure to fabricate others of microelectronic assembly 100 disclosed herein.

FIG. 8A illustrates a core 103 including a first surface 170-1 and a second surface 170-2. FIG. 8B illustrates an assembly subsequent to forming via openings 511 through the core 103. The via openings 511 may be formed using any suitable process, including lithography, laser assisted wet etch, laser drilling (e.g., laser ablation using excimer laser), or plasma etching. The via openings 511 may have any suitable shape. For example, the via openings 511 may have substantially vertical sidewalls to form rectangular-shaped vias, as shown, or may have angled sidewalls to form conical-shaped vias. The shape of the via openings 511 may depend on the process used to form the via openings 511 (e.g., a lithographic process for rectangular-shaped vias and a laser drilling process for conical-shaped vias).

FIG. 8C illustrates an assembly subsequent to depositing a conductive material in the via openings of FIG. 8B to form TGVs 110 and patterning a conductive material on a surface to form conductive contacts 172, 174. A conductive material may include any suitable material, such as copper. The conductive material may be deposited using any suitable process, including lithography, sputtering, electrolytic plating, or electroless plating.

FIG. 8D illustrates an assembly subsequent to forming a dielectric material 107-1 on a bottom surface 170-1 of the core 103, forming a dielectric material 107-2 on a top surface 170-2 of the core 103, and forming conductive pathways 196 through the dielectric material 107-1, 107-2. The assembly of FIG. 8D may be manufactured using conventional package substrate manufacturing techniques. The dielectric material 107 may include thermal isomeric and non-thermal isomeric moieties as described above with reference to FIGS. 1-6.

FIG. 8E illustrates an assembly subsequent to forming conventional dielectric materials 109-1, 109-2 on the respective dielectric materials 107-1, 107-2 to form substrates 148-1, 148-2, placing dies 114-1, 114-2 on a top surface of the conventional dielectric material 109-2, forming interconnects 150, and depositing an underfill material 127 around the interconnects 150. Any suitable method may be used to place the dies 114-1, 114-2, for example, automated pick-and-place. In some embodiments, the interconnects 150 may include solder. In such embodiments, the assembly of FIG. 8E may be subjected to a solder reflow process during which solder components of the interconnects 150 melt and bond to mechanically and electrically couple the dies 114-1, 114-2 to the top surface of the assembly of FIG. 8E. In some embodiments, an insulating material 133 (e.g., as shown in FIG. 7A) may be deposited on and around the dies 114-1, 114-2. In such embodiments, the underfill 127 may be dispensed around the interconnects 150 prior to depositing the insulating material 133. In some embodiments, underfill 127 around the interconnects 150 may be omitted. If multiple assemblies are manufactured together, the assemblies may be singulated. The assembly of FIG. 8E may itself be a microelectronic assembly 100, as shown. Further manufacturing operations may be performed on the microelectronic assembly 100 of FIG. 8E to form other microelectronic assembly 100; for example, solder may be deposited on conductive contacts 172 at a bottom surface of the first substrate 148-1 and used to couple the microelectronic assembly 100 of FIG. 8E to a circuit board 131 by interconnects 190, similar to the microelectronic assembly 100 of FIG. 1.

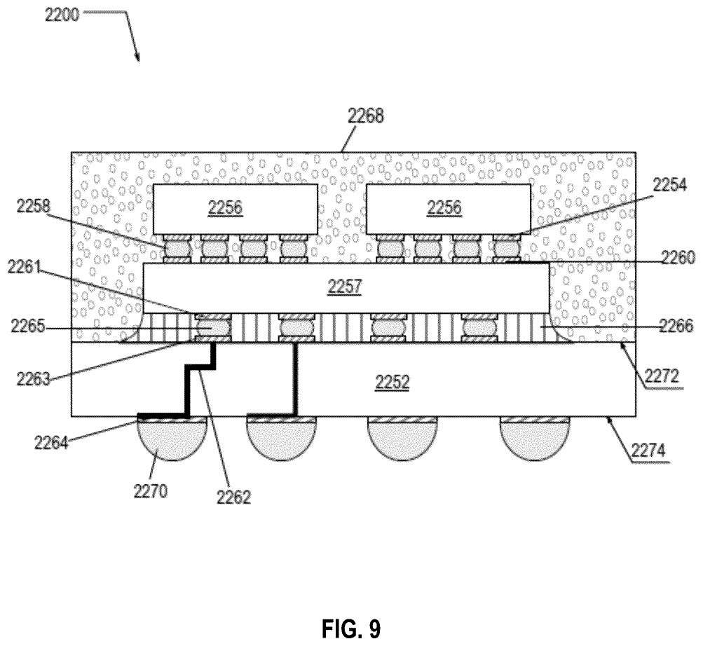

The packages disclosed herein, e.g., any of the microelectronic assemblies 100, or any further embodiments described herein, may be included in any suitable electronic component. FIGS. 9-11 illustrate various examples of packages, assemblies, and devices that may be used with or include any of the IC packages as disclosed herein.

FIG. 9 is a side, cross-sectional view of an example IC package 2200 that may include microelectronic assemblies in accordance with any of the embodiments disclosed herein. In some embodiments, the IC package 2200 may be a system-in-package (SiP).

As shown in FIG. 7, package support 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures including lines and/or vias.

Package support 2252 may include conductive contacts 2263 that are coupled to conductive pathway 2262 through package support 2252, allowing circuitry within dies 2256 and/or interposer 2257 to electrically couple to various ones of conductive contacts 2264 (or to other devices included in package support 2252, not shown).

IC package 2200 may include interposer 2257 coupled to package support 2252 via conductive contacts 2261 of interposer 2257, first level interconnects (FLI) 2265, and conductive contacts 2263 of package support 2252. FLI 2265 illustrated in FIG. 9 are solder bumps, but any suitable FLI 2265 may be used, such as solder bumps, solder posts, or bond wires.

IC package 2200 may include one or more dies 2256 coupled to interposer 2257 via conductive contacts 2254 of dies 2256, FLI 2258, and conductive contacts 2260 of interposer 2257. In various embodiments, interposer 2257 may include core 103 including glass as described herein. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). FLI 2258 illustrated in FIG. 9 are solder bumps, but any suitable FLI 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

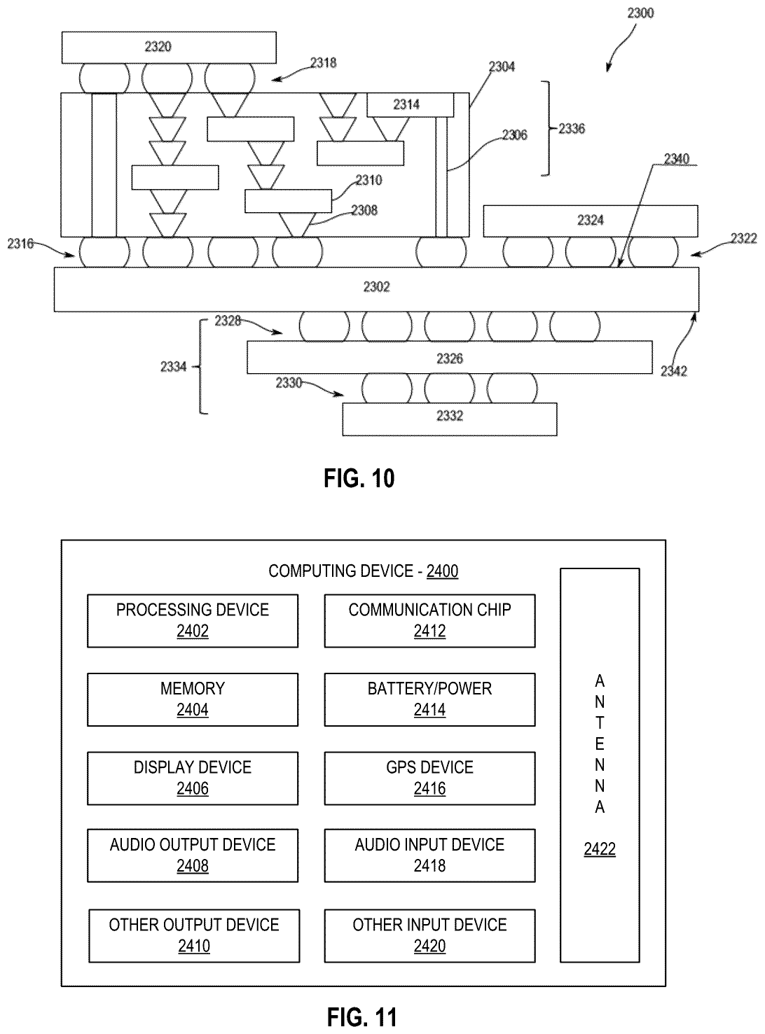

In some embodiments, underfill material 2266 may be disposed between package support 2252 and interposer 2257 around FLI 2265, and mold 2268 may be disposed around dies 2256 and interposer 2257 and in contact with package support 2252. In some embodiments, underfill material 2266 may be the same as mold 2268. Example materials that may be used for underfill material 2266 and mold 2268 are epoxies as suitable. Second level interconnects (SLI) 2270 may be coupled to conductive contacts 2264. SLI 2270 illustrated in FIG. 9 are solder balls (e.g., for a ball grid array (BGA) arrangement), but any suitable SLI 2270 may be used (e.g., pins in a pin grid array arrangement or lands in a land grid array arrangement). SLI 2270 may be used to couple IC package 2200 to another component, such as a circuit board (e.g., a motherboard), an interposer, or another IC package, as known in the art and as discussed below with reference to FIG. 10.

In embodiments in which IC package 2200 includes multiple dies 2256, IC package 2200 may be referred to as a multichip package (MCP). Dies 2256 may include circuitry to perform any desired functionality. For example, besides one or more of dies 2256 including components of dies 114 as described herein, one or more of dies 2256 may be logic dies (e.g., silicon-based dies), one or more of dies 2256 may be memory dies (e.g., high-bandwidth memory), etc. In some embodiments, at least some of dies 2256 may not include components of dies 114 as described herein.

Although IC package 2200 illustrated in FIG. 9 is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package support 2252, or on either face of interposer 2257. More generally, IC package 2200 may include any other active or passive components known in the art.

FIG. 10 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 7.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package support.

FIG. 10 illustrates that, in some embodiments, IC device assembly 2300 may include a package-on-interposer structure 2336 coupled to first face 2340 of circuit board 2302 by coupling components 2316. Although not shown so as not to clutter the drawing, package-on-interposer structure 2336 may include a core 103, such as glass layer, in some embodiments. In other embodiments, package-on-interposer structure 2336 may not include a core. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. In some embodiments, IC package 2320 may include microelectronic assembly 100, and other components as described herein, which are not shown so as not to clutter the drawing. Coupling components 2318 may take any suitable form depending on desired functionalities, such as the forms discussed above with reference to coupling components 2316. In some embodiments, IC package 2320 may be or include IC package 2200, e.g., as described above with reference to FIG. 7.

Although a single IC package 2320 is shown in FIG. 8, multiple IC packages may be coupled to interposer 2304; indeed, additional interposers may be coupled to interposer 2304. Interposer 2304 may provide an intervening package support used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in FIG. 8, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including TSVs 2306. Interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

FIG. 11 is a block diagram of an example computing device 2400 that may include one or more components having one or more IC packages in accordance with any of the embodiments disclosed herein. For example, any suitable ones of the components of computing device 2400 may include microelectronic assembly 100 including glass in accordance with any of the embodiments disclosed herein. In another example, any one or more of the components of computing device 2400 may include any embodiments of IC package 2200 (e.g., as shown in FIG. 7). In yet another example, any one or more of the components of computing device 2400 may include an IC device assembly 2300 (e.g., as shown in FIG. 8).

A number of components are illustrated in FIG. 11 as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in FIG. 10, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more digital signal processors (DSPs), ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips; note that the terms “chip,” “die,” and “IC die” are used interchangeably herein). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives of it, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

The following paragraphs provide various examples of the embodiments disclosed herein.

Example 1 is a microelectronic assembly, including a glass layer having a surface, the glass layer including conductive through-glass vias (TGVs); and a substrate layer on the surface of the glass layer, the substrate layer including a dielectric material and conductive pathways through the dielectric material, wherein the dielectric material includes an epoxy having thermal isomeric linkages, non-thermal isomeric linkages, and non-thermal isomeric epoxy monomers, and wherein the thermal isomeric linkages include a cis-dibenzocyclooctane (DBCO) moiety or a tetra derivative DBCO moiety.

Example 2 may include the subject matter of Example 1, and may further specify that the dielectric material has a co-efficient of thermal expansion above a glass transition temperature (CTE-2) between 5 ppm/° C. and 55 ppm/° C.

Example 3 may include the subject matter of Examples 1 or 2, and may further specify that the non-thermal isomeric linkages include an aromatic moiety or an aliphatic moiety.

Example 4 may include the subject matter of any of Examples 2-4, and may further specify that the substrate layer is a first substrate layer including a first dielectric material, and the microelectronic assembly may further include a second substrate layer on the first substrate layer, the second substrate layer including a second dielectric material, wherein the second dielectric material includes the epoxy having the thermal isomeric linkages, the non-thermal isomeric linkages, and the non-thermal isomeric epoxy monomers, and wherein the second dielectric material has a CTE-2 between 25 ppm/° C. and 65 ppm/° C.

Example 5 may include the subject matter of any of Examples 2-4, and may further specify that the substrate layer is a first substrate layer including a first dielectric material, and the microelectronic assembly may further include a second substrate layer on the first substrate layer, the second substrate layer including a second dielectric material, wherein the second dielectric material has a CTE-2 between 30 ppm/° C. and 110 ppm/° C.

Example 6 may include the subject matter of Example 5, and may further include a third substrate layer between the first substrate layer and the second substrate layer, the third substrate layer including a third dielectric material, wherein the third dielectric material includes the epoxy having the thermal isomeric linkages, the non-thermal isomeric linkages, and the non-thermal isomeric epoxy monomers, and wherein the second dielectric material has a CTE-2 between 25 ppm/° C. and 65 ppm/° C.

Example 7 may include the subject matter of Example 1, and may further include a die on the substrate layer and electrically coupled to some of the conductive pathways in the substrate layer.

Example 8 may include the subject matter of Example 7, and may further include an interconnect die at least partially within the dielectric material of the substrate layer and electrically coupled to the die.

Example 9 is a microelectronic assembly, including a glass layer having a surface, the glass layer including conductive through-glass vias (TGVs); and a substrate layer on the surface of the glass layer, the substrate layer including a dielectric material and conductive pathways through the dielectric material, wherein the dielectric material includes an epoxy having thermal isomeric epoxy monomers, non-thermal isomeric epoxy monomers, and non-thermal isomeric linkages, and wherein the thermal isomeric epoxy monomers include a cis-dibenzocyclooctane (DBCO) moiety or a tetra derivative DBCO moiety.

Example 10 may include the subject matter of Example 9, and may further specify that the dielectric material has a co-efficient of thermal expansion above a glass transition temperature (CTE-2) between 5 ppm/° C. and 55 ppm/° C.

Example 11 may include the subject matter of Examples 9 or 10, and may further specify that the non-thermal isomeric epoxy monomers include an aromatic moiety or an aliphatic moiety.

Example 12 may include the subject matter of Examples 10 or 11, and may further specify that the substrate layer is a first substrate layer including a first dielectric material, and the microelectronic assembly may further include a second substrate layer on the first substrate layer, the second substrate layer including a second dielectric material, wherein the second dielectric material includes the epoxy having the thermal isomeric epoxy monomers, the non-thermal isomeric epoxy monomers, and the non-thermal isomeric linkages, and wherein the second dielectric material has a CTE-2 between 25 ppm/° C. and 65 ppm/° C.

Example 13 may include the subject matter of Examples 10 or 11, and may further specify that the substrate layer is a first substrate layer including a first dielectric material, and the microelectronic assembly may further include a second substrate layer on the first substrate layer, the second substrate layer including a second dielectric material, wherein the second dielectric material has a CTE-2 between 30 ppm/° C. and 110 ppm/° C.

Example 14 may include the subject matter of Example 13, and may further include a third substrate layer between the first substrate layer and the second substrate layer, the third substrate layer including a third dielectric material, wherein the third dielectric material includes the epoxy having the thermal isomeric epoxy monomers, the non-thermal isomeric epoxy monomers, and the non-thermal isomeric linkages, and wherein the second dielectric material has a CTE-2 between 25 ppm/° C. and 65 ppm/° C.

Example 15 may include the subject matter of Example 9, and may further specify that the surface of the glass layer is a first surface and the glass layer further includes a second surface opposite the first surface, wherein the substrate layer is a first substrate layer on the first surface of the glass layer including a first dielectric and first conductive pathways, and the microelectronic assembly may further include a second substrate layer on the second surface of the glass layer, the second substrate layer including a second dielectric material and second conductive pathways through the second dielectric material, wherein the second dielectric material includes the epoxy having the thermal isomeric epoxy monomers, the non-thermal isomeric epoxy monomers, and the non-thermal isomeric linkages, and wherein the thermal isomeric epoxy monomers include a cis-dibenzocyclooctane (DBCO) moiety or a tetra derivative DBCO moiety.

Example 16 may include the subject matter of Example 15, and may further specify that the second dielectric material has a co-efficient of thermal expansion above a glass transition temperature (CTE-2) between 5 ppm/° C. and 55 ppm/° C.

Example 17 is a microelectronic assembly, including a glass layer having a surface, the glass layer including conductive through-glass vias (TGVs); and a substrate layer on the surface of the glass layer, the substrate layer including a dielectric material and conductive pathways through the dielectric material, wherein the dielectric material includes a bismaleimide resin or a polyimide resin having thermal isomeric monomers and non-thermal isomeric monomers, wherein the thermal isomeric monomers include a cis-dibenzocyclooctane (DBCO) moiety or a tetra derivative DBCO moiety.

Example 18 may include the subject matter of Example 17, and may further specify that the dielectric material has a co-efficient of thermal expansion above a glass transition temperature (CTE-2) between 5 ppm/° C. and 55 ppm/° C.

Example 19 may include the subject matter of Examples 17 or 18, and may further specify that the non-thermal isomeric monomers include an aromatic moiety or an aliphatic moiety.

Example 20 may include the subject matter of Examples 18 or 19, and may further specify that the substrate layer is a first substrate layer including a first dielectric material, and the microelectronic assembly may further include a second substrate layer on the first substrate layer, the second substrate layer including a second dielectric material, wherein the second dielectric material has a CTE-2 between 30 ppm/° C. and 110 ppm/° C.

Example 21 may include the subject matter of any of Examples 17-19, and may further include a die on the substrate layer and electrically coupled to some of the conductive pathways in the substrate layer.

Example 22 may include the subject matter of Example 21, and may further include an insulating material surrounding the die.

Example 23 may include the subject matter of any of Examples 17-22, and may further specify that a thickness of the glass layer is between 25 microns and 2 millimeters.

1. A microelectronic assembly, comprising:
a glass layer having a surface, the glass layer including conductive through-glass vias (TGVs); and
a substrate layer on the surface of the glass layer, the substrate layer including a dielectric material and conductive pathways through the dielectric material, wherein the dielectric material includes an epoxy having thermal isomeric linkages, non-thermal isomeric linkages, and non-thermal isomeric epoxy monomers, and wherein the thermal isomeric linkages include a cis-dibenzocyclooctane (DBCO) moiety or a tetra derivative DBCO moiety.

2. The microelectronic assembly of claim 1, wherein the dielectric material has a co-efficient of thermal expansion above a glass transition temperature (CTE-2) between 5 ppm/° C. and 55 ppm/° C.

3. The microelectronic assembly of claim 1, wherein the non-thermal isomeric linkages include an aromatic moiety or an aliphatic moiety.

4. The microelectronic assembly of claim 2, wherein the substrate layer is a first substrate layer including a first dielectric material, and the microelectronic assembly further comprising:
a second substrate layer on the first substrate layer, the second substrate layer including a second dielectric material, wherein the second dielectric material includes the epoxy having the thermal isomeric linkages, the non-thermal isomeric linkages, and the non-thermal isomeric epoxy monomers, and wherein the second dielectric material has a CTE-2 between 25 ppm/° C. and 65 ppm/° C.

5. The microelectronic assembly of claim 2, wherein the substrate layer is a first substrate layer including a first dielectric material, and the microelectronic assembly further comprising:
a second substrate layer on the first substrate layer, the second substrate layer including a second dielectric material, wherein the second dielectric material has a CTE-2 between 30 ppm/° C. and 110 ppm/° C.

6. The microelectronic assembly of claim 5, further comprising:
a third substrate layer between the first substrate layer and the second substrate layer, the third substrate layer including a third dielectric material, wherein the third dielectric material includes the epoxy having the thermal isomeric linkages, the non-thermal isomeric linkages, and the non-thermal isomeric epoxy monomers, and wherein the second dielectric material has a CTE-2 between 25 ppm/° C. and 65 ppm/° C.

7. The microelectronic assembly of claim 1, further comprising:
a die on the substrate layer and electrically coupled to some of the conductive pathways in the substrate layer.

8. The microelectronic assembly of claim 7, further comprising:
an interconnect die at least partially within the dielectric material of the substrate layer and electrically coupled to the die.

9. A microelectronic assembly, comprising:
a glass layer having a surface, the glass layer including conductive through-glass vias (TGVs); and
a substrate layer on the surface of the glass layer, the substrate layer including a dielectric material and conductive pathways through the dielectric material, wherein the dielectric material includes an epoxy having thermal isomeric epoxy monomers, non-thermal isomeric epoxy monomers, and non-thermal isomeric linkages, and wherein the thermal isomeric epoxy monomers include a cis-dibenzocyclooctane (DBCO) moiety or a tetra derivative DBCO moiety.

10. The microelectronic assembly of claim 9, wherein the dielectric material has a co-efficient of thermal expansion above a glass transition temperature (CTE-2) between 5 ppm/° C. and 55 ppm/° C.

11. The microelectronic assembly of claim 9, wherein the non-thermal isomeric epoxy monomers include an aromatic moiety or an aliphatic moiety.

12. The microelectronic assembly of claim 10, wherein the substrate layer is a first substrate layer including a first dielectric material, and the microelectronic assembly further comprising:
a second substrate layer on the first substrate layer, the second substrate layer including a second dielectric material, wherein the second dielectric material includes the epoxy having the thermal isomeric epoxy monomers, the non-thermal isomeric epoxy monomers, and the non-thermal isomeric linkages, and wherein the second dielectric material has a CTE-2 between 25 ppm/° C. and 65 ppm/° C.

13. The microelectronic assembly of claim 10, wherein the substrate layer is a first substrate layer including a first dielectric material, and the microelectronic assembly further comprising:
a second substrate layer on the first substrate layer, the second substrate layer including a second dielectric material, wherein the second dielectric material has a CTE-2 between 30 ppm/° C. and 110 ppm/° C.

14. The microelectronic assembly of claim 13, further comprising:
a third substrate layer between the first substrate layer and the second substrate layer, the third substrate layer including a third dielectric material, wherein the third dielectric material includes the epoxy having the thermal isomeric epoxy monomers, the non-thermal isomeric epoxy monomers, and the non-thermal isomeric linkages, and wherein the second dielectric material has a CTE-2 between 25 ppm/° C. and 65 ppm/° C.

15. The microelectronic assembly of claim 9, wherein the surface of the glass layer is a first surface and the glass layer further includes a second surface opposite the first surface, wherein the substrate layer is a first substrate layer on the first surface of the glass layer including a first dielectric and first conductive pathways, and the microelectronic assembly further comprising:
a second substrate layer on the second surface of the glass layer, the second substrate layer including a second dielectric material and second conductive pathways through the second dielectric material, wherein the second dielectric material includes the epoxy having the thermal isomeric epoxy monomers, the non-thermal isomeric epoxy monomers, and the non-thermal isomeric linkages, and wherein the thermal isomeric epoxy monomers include a cis-dibenzocyclooctane (DBCO) moiety or a tetra derivative DBCO moiety.

16. The microelectronic assembly of claim 15, wherein the second dielectric material has a co-efficient of thermal expansion above a glass transition temperature (CTE-2) between 5 ppm/° C. and 55 ppm/° C.

17. A microelectronic assembly, comprising:
a glass layer having a surface, the glass layer including conductive through-glass vias (TGVs); and
a substrate layer on the surface of the glass layer, the substrate layer including a dielectric material and conductive pathways through the dielectric material, wherein the dielectric material includes a bismaleimide resin or a polyimide resin having thermal isomeric monomers and non-thermal isomeric monomers, wherein the thermal isomeric monomers include a cis-dibenzocyclooctane (DBCO) moiety or a tetra derivative DBCO moiety.

18. The microelectronic assembly of claim 17, wherein the dielectric material has a co-efficient of thermal expansion above a glass transition temperature (CTE-2) between 5 ppm/° C. and 55 ppm/° C.

19. The microelectronic assembly of claim 17, wherein the non-thermal isomeric monomers include an aromatic moiety or an aliphatic moiety.

20. The microelectronic assembly of claim 18, wherein the substrate layer is a first substrate layer including a first dielectric material, and the microelectronic assembly further comprising:
a second substrate layer on the first substrate layer, the second substrate layer including a second dielectric material, wherein the second dielectric material has a CTE-2 between 30 ppm/° C. and 110 ppm/° C.
